(19) United States
(12) Patent Application Publication
(10) Pub. No.: US 2026/0010673 A1
(43) Pub. Date: Jan. 8, 2026

(54) METHOD FOR MODELING AND SIMULATING A SYSTEM OF SYSTEMS

(71) Applicant: C.E.S.A.M.E.S. Systemic Intelligence PTE. LTD., Singapore (SG)

(72) Inventors: Daniel Krob, Paris (FR); Antoine Rauzy, Trondheim (NO)

(21) Appl. No.: 18/839,305

(22) PCT Filed: Feb. 21, 2023
(86) PCT No.: PCT/IB2023/051572

§ 371 Date: Feb. 25, 2025

(30) Foreign Application Priority Data
Feb. 25, 2022 (FR) FR2201683

(51) Int. Cl. G06F 30/20; G06Q 10/04

(52) U.S. Cl. CPC G06F 30/20; G06Q 10/04

(57) ABSTRACT

A method for modeling and simulating a system of systems, involving a technical system of interest as well as of a plurality of systems external to the technical system of interest, forming the environment wherein the system of interest evolves.

### CROSS-REFERENCE TO RELATED APPLICATIONS

This application is a national phase entry under 35 U.S.C. § 371 of International Patent Application PCT/IB2023/051572, filed Feb. 21, 2023, designating the United States of America and published as International Patent Publication WO 2023/161793 A1 on Aug. 31, 2023, which claims the benefit under Article 8 of the Patent Cooperation Treaty of French Patent Application Serial No. FR2201683, filed Feb. 25, 2022.

### TECHNICAL FIELD

The present disclosure relates to asset lifecycle management, and more specifically, planning analysis for asset lifecycle management.

### BACKGROUND

Known in the state of the art is the article-Jie Zhang et al, Supply-chain Digital Twin Framework Design: An Approach of Supply-chain Operations Reference Model and System of Systems, Cornell University Library Ithaca, Jul. 19, 2021.

This document describes the general principle of using digital twins in the supply chain. It proposes general rules for building such digital twins in the context of supply chains.

The article introduces two digital twin concepts:
a restricted concept of geometric digital twin focused on system visualization; and
a broader concept of digital twins for system simulation, control, evaluation, regulation and monitoring. This second digital twin concept is characterized by 1) the physical space, 2) the virtual space, 3) the data, 4) the services offered and 5) the connection mechanisms between these components.

The article then briefly introduces the notion of a system of systems, highlighting one of the fundamental characteristics of this type of system, namely the autonomy of its components, and explains that a supply chain is indeed a system of systems.

It then introduces the reference business model for supply chain operations defined by the American Supply-chain Association. This is organized around five business processes (planning, sourcing, producing, delivering, managing returns) which are refined into four levels of granularity.

With these foundations laid, the article presents a framework for digital twins for the supply-chain based on four steps to build a digital twin for a supply-chain:
1. Modularizing: the first step is to analyze the supply-chain in a modular way, breaking it down into a hierarchy of 4 levels: the supply-chain system, parts of the system, modules of these parts, and blocks of these modules;
2. Digitizing core activities: each core activity involved in managing a supply chain must then be digitized, with the article recommending that this digitizing work be carried out using existing components of a company's information system covering the activities concerned;
3. Developing digital sub-twins for parts of the system: digital sub-twins must then be developed on an ad hoc basis for each part of the supply-chain system (in the sense of the modular decomposition introduced in step 1), by constructing the analysis mechanisms to be carried out and the indicators to be returned, based on the digitizing of basic activities (in the sense of step 2);
4. Integrating: the final step involves integrating all the digital sub-twins obtained in step 3 (see the following diagram for an illustration).

The article goes on to present a number of relatively general business and technical principles to ensure the successful integration of a digital twin using the proposed method.

A case study of a small supply chain (2 suppliers, 1 carrier, 1 factory, 2 distributors) then illustrates the proposed framework for digital twins for the supply chain.

Also known is the article by Arrichiello Vincenzo et al, Systems engineering and digital twin: a vision for the future of cruise ships design, production and operations, International Journal on Interactive Design and Manufacturing, Vol. 14, N-∞ 1, pp. 115-122, 2019.

This article shows how model-based systems engineering techniques can be used to improve the design of cruise ships, which are characterized by the need to reconcile extremely high levels of operational performance and dependability. He introduces a presentation of systems engineering with a focus on model-driven systems engineering, which leads him to introduce the notion of model, segmented into descriptive and analytical models, and then to pose the problem of alignment between a model and the physical system it models, enabling him to introduce the concept of a digital twin of a given physical system.

This prior art document then goes on to analyze the value of the digital twin concept for capturing the entire life cycle of a cruise ship. This section begins with purely business considerations, then highlights the possibility of feeding a digital twin with data from sensors placed on the real system it models so that the digital twin can acquire predictive capabilities to minimize risk and improve profitability on a cruise ship. He goes on to explain how to achieve user-centered design using a digital twin, which is indeed important in the context of a cruise ship where the needs of passengers, crew and owner play key roles in the design of such a system. The four properties of the digital twin highlighted by the article at this level include:
1. Ability to validate a system model with real data;
2. Ability to provide decision support and alerts to users;
3. Ability to predict changes in a physical system over time; and
4. Ability to discover new opportunities in terms of services and sources of revenue.

The usefulness of a digital twin for better design of the structure, machinery (propulsion chain), organization of passenger spaces and operational safety is then briefly discussed, before finally evoking the difference between the computer-aided design approach and that of the digital twin, which, in particular, makes it possible to capture the evolution of a cruise ship over the course of its life, in the specific context of the article. In particular, this document does not present any architecture principles for a digital twin and merely gives business motivations justifying the benefit of a digital twin in the specific context of cruise ship design.

Finally, known also is the article by Madni Azad M. et al, Digital Twin-enabled MBSE Testbed for Prototyping and Evaluating Aerospace Systems: Lessons Learned, 2021 IEEE Aerospace Conference, p. 1-8, Mar. 6, 2021. It presents a model-driven systems engineering approach for the design of drone swarms. This is based on a set of independent tools-referred to as “test benches” in the article—offering different types of simulation mechanisms (agent-oriented, behavioral, Monte-Carlo, discrete-event, continuous, state machines).

This article then explains the features that distinguish the proposed approach from a classic “hardware in the loop” approach, namely the ability to obtain different views of the system under study, to manage dynamically reconfigurable systems via agent-oriented modeling, to compose systems, to collect evidence, to exploit feedback from a system, to explicitly address the temporal dimension of systems, to take into account the impacts of change and to validate models, without however going into any detail. This is followed by a brief description of the components of the proposed “test bench,” which is intended to function as a digital twin for the drone swarms under consideration. The article then briefly describes how the proposed test bench has been implemented at IT level, as well as the structure of the intelligent dashboards that enable this test bench to be controlled via scenario simulation, a scenario being characterized here by one or more objectives, the physical space where the scenario takes place, the events that may occur and the structure of the interface for user feedback. It also explains how digital twins—of a purely geometric nature—of the terrain and a quadricopter (the basic component of a swarm) can be integrated into the proposed test bench.

Prior art solutions for digital twins focus mainly on digital geometric models and data feeds via the Internet of Things (IoT). This approach is inadequate, as it cannot capture the behaviors of the underlying industrial systems, and especially the end-to-end functional behaviors of these systems that cannot be observed either locally or geometrically (e.g., the overall yield of a manufacturing production line). In particular, a digital twin must be able to model and simulate these behaviors globally, starting from operational data and feeding into strategic decision-making dashboards. Existing solutions, which work with raw data without being able to abstract it into synthetic, systemic data, fail to do this.

In addition, existing solutions focused specifically on asset management generally lack the richness of digital twins, because the physical and digital models they manipulate are generally centered locally on the management of the assets they supervise, without taking into account their technical, business and external environments in their entirety (e.g., evolution of needs, budgetary constraints, strategic choices, evolution of regulations, environmental footprint, weather, input/output flow physics, safety and security, etc.) and the influence of these environments on the evolution of assets: a digital twin must be able to model and simulate the impact of the environment on assets, something that existing solutions are unable to do because they do not integrate this dimension.

### BRIEF SUMMARY

Asset management within the meaning of this patent refers to the management of the assets of a technical entity, such as an infrastructure or an industrial site, considered as a complex technical system made up of several pieces of equipment and resources interacting together, with the aim of maximizing the value of the assets throughout their life cycle and optimizing the performance and operating modes of the assets, reducing the capital costs of the assets as well as the operating costs related to the assets and extending the life of the assets.

To achieve this, it is proposed to construct digital twins of the infrastructures and industrial sites to be managed, based on a model that enables predictive simulations or synchronized supervision to be carried out integrating the actual evolution of the associated system.

The development of the Industrial Internet of Things (IIOT) and cloud platform technologies is also facilitating the deployment of value-added industrial services such as remote monitoring, intelligent operation and maintenance, professional optimization and more.

The development of next-generation information technologies provides powerful support for these industrial services, and a digital twin, in particular, provides a technical means for the interactive fusion of an information domain and a physical domain. Digital twins are virtual digital technical objects associated with physical entities whose behavior in a real environment is simulated using data. The technical capabilities of physical entities are modified by way of virtual-real interaction feedback, data fusion analysis, iterative decision optimization, and so on.

The use of digital twins enables the entire lifecycle process of a technical system and its components to be supervised, as the current state of the technical system can be reflected in real time in the digital twin, and ensures real-time optimization and maintenance of decisions and forecasts based on perception information.

The real-time, bi-directional, closed-loop dynamics of a digital twin make it possible to monitor, verify, simulate, predict and optimize, according to specific objectives, the technical activities of the physical entity supervised by this means, with digital twinning ensuring the synchronization of the interaction of physical entities with digital artifacts.

State parameters of physical entities can be reliably and efficiently measured and transmitted to the digital twin, so that the latter accurately reflects the actual technical state of a physical entity. As state variables and parameter setpoints change on the digital twin, the associated information is fed back to the physical entity, so that the behavior and technical state of the physical entity can be adjusted.

In the industrial sector, the use of fieldbus technology to acquire data from technical equipment is mature and widely applied. However, the Industrial Internet of Things (IIoT) has moved beyond the industrial perimeter, connecting to the wider Internet. Wireless communication technology (GPRS, 4G, 5G, LPWAN, etc.) is widely used, and the stability and bandwidth of connections have a major influence on the degree of virtual-real interaction, making overall security more difficult to guarantee, for example. Consequently, the method of virtual-real synchronization of the physical entity and the digital twin is a problem that deserves in-depth study.

The present disclosure enables optimal management of the life cycle of industrial and technical assets, taking into account both their functional behavior, particularly end-to-end, and the environmental constraints associated with the assets in question. The aim of the present disclosure is to provide a tool to help operators of complex industrial infrastructures to better manage the lifecycle of their assets and optimize their overall operations, using new-generation decision-support tools based on systemic approaches: systemic digital twins. A typical problem to be addressed in this way is maximizing the overall performance of an industrial system while minimizing its environmental footprint.

Embodiments include a systemic modeling language and methodology, a set of computer programs, and an associated hardware architecture for implementing a systemic digital twin manager for the assets under consideration. The aim of this systemic digital twin manager is twofold: firstly, to study the possible evolution of assets due to internal causes or changes in their environment, including the design and management of systemic evolution scenarios, the calculation of their probability and the risk they present for assets; secondly, to issue systemic alerts when the identified systemic evolution scenarios, their probability or their risk deviate from what was initially considered acceptable.

In its most general sense, the present disclosure concerns a method for modeling and simulating a system of systems, consisting of a technical system of interest and a plurality of systems external to the technical system of interest, forming the environment wherein the system of interest evolves, comprising the following steps:
A step of designing one or more scalable digital models of the system of systems, including recording the following elements in digital files:
   A description of the system of interest in a hierarchy of systems, comprising for each system a plurality of descriptors of the components of the system (individual states of the components, levels of stocks handled by the components, performance indicators of the components, etc.) and of parameters associated with each of the systems, each of the components being itself modelable as a system, down to the level of an elementary object;
   A description of the environment of the system of interest comprising, for each external system with which the system of interest interacts, a hierarchical description similar to that of the latter;
   A description of the actions performed by each of the systems involved and the interactions between these systems, including:
      A plurality of descriptors of the laws of internal evolution of their components and the laws of dynamic interactions between the system and the other systems with which it interacts;
      These interaction laws can change, create, destroy or move one or more systems in the hierarchy, can have deterministic or stochastic effects (governed by probabilistic laws), and are temporized, that is, associated with execution times, again deterministic or stochastic, and each system can have its own temporality.
A step of configuring this digital model comprising the following steps:
   Collecting data sets corresponding to the description of static and/or dynamic parameters for the evolution of the systems in question, which may call on internal or external databases;
   Injecting these data sets into the digital model(s) in the appropriate format;
   Defining the key performance indicators to be assessed, in order to support decision-making during the design, deployment, operation, maintenance and even dismantling of the system of interest.
A numerical simulation step enabling the above-mentioned performance indicators to be effectively evaluated, this step comprising the following sub-steps:
   Defining simulation scenarios involving a plurality of iterations (so-called Monte-Carlo simulation) and statistical processing of the calculated values of the performance indicators;
   The actual execution of these simulation scenarios on a set of control units, taking into account the load on each of the control units; and
   Possibly raising alarms in the event that the simulations reveal scenarios of evolution of the system of interest presenting a material, economic or environmental risk for the system of interest, its operators, or the systems with which it interacts, as well as the operators of the systems.

For the purposes of the present disclosure, “model” means a formal specification of the system of systems under consideration, with unambiguous mathematical semantics.

### BRIEF DESCRIPTION OF THE DRAWINGS

The present disclosure will be better understood on reading the following description, which concerns a non-limiting exemplary embodiment that is shown by the appended drawings, in which:

FIG. 1 shows a schematic view of the technical architecture according to the present disclosure.

### DETAILED DESCRIPTION

The present disclosure generally relates to the strategic management of assets in industrial companies and public organizations, and more specifically, the on-the-fly detection of any potentially risky evolution of these assets, resulting either from internal problems or drastic changes in the environment, or both.

The present disclosure is based on two interlocking technical sub-assemblies:
1. The systemic digital twin, as described, to improve the technical performance of its physical twin.
2. The proposed architecture to improve the performance of the digital twin creation and maintenance process.

Strategic asset management involves managing the assets of an entity, such as an industrial production company, a technical infrastructure operator or a public agency, by establishing possible scenarios of systemic evolution, classifying these scenarios according to their probability and the risk they present for the assets, their owners and their environment, assessed through computerized simulations, monitoring environmental conditions, and finally issuing alerts when the identified scenarios, their probability or their risk deviate from what was initially considered acceptable.

The present disclosure implements on-the-fly detection of serious drifts in operations resulting either from internal problems, drastic changes in the environment, or both.

The objectives of the present disclosure generalize those of US patent 2014/0330747 A1. The underlying technologies and fields of application are, however, substantially different.

### Architecture

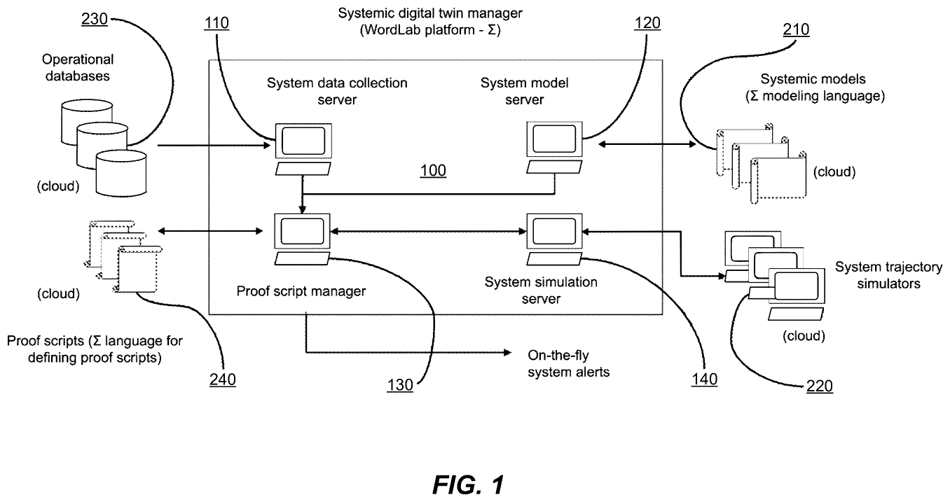

FIG. 1 shows the hardware architecture of a systemic digital twin designed according to one embodiment of the present disclosure.

It comprises a systemic twinning management system (100) comprising a systemic data extraction server (110), a systemic model management server (120), a systemic evidence manager (130) and a systemic simulation server (140). The present disclosure implements a modeling language accessible in the cloud in the form of scripts (210). The systemic twinning manager system (100) communicates with systemic trajectory simulation equipment (220). The data are stored in transaction data servers (230) and in the form of proof scripts (240).

The present disclosure's strategic asset management solution is based on the design and simulation of systemic digital twins of the assets under consideration. These systemic digital twins aim to describe scenarios of asset use and their possible systemic evolution as a function of internal and external changes.

The scenarios incorporate operational data from the field, which is continuously updated. Once described and updated, these scenarios of use and systemic evolution can be simulated in order to classify them according to their probability and the risk they present for the assets. Based on the results of the simulations, systemic alerts can be issued, prompting asset preservation actions or adjustments to asset management policies, to reflect corresponding internal and external developments. The architecture of the present disclosure's embodiments thus makes it possible to combine and integrate descriptive, predictive and prescriptive analyses.

The modes of implementation are based on four pillars: the design and management of system models describing scenarios using the 2 (Sigma) modeling language, the continuous updating of operational field data integrated into these system models by way of a dedicated system data consolidation server, the design and management of scripts, known as system proofs, that describe which key performance indicators are to be calculated by way of computerized system simulations, and finally a system simulation technology for distributing the simulations and collecting their results.

### Systemic Data Extraction Services

In one embodiment, systemic models involve data distributions and chronological series, such as market prices for barrels of oil or reliability data for electronic components.

To enable an accurate assessment of the probability of scenarios and their ranking in relation to the risks they present to assets, these data are continually updated. A dedicated systemic data extraction server (110) runs data mining scripts that extract data from internal or external databases and put it into a form that can be integrated into system models.

### Design and Management of Σ (Sigma) Models

In one embodiment, systemic models are designed in the Σ (Sigma) object-oriented modeling language [Krob & Rauzy, 2022, A Guided Tour of the Modeling Language Σ, CESAMES Systemic Intelligence Pte. Ltd.], belonging to the S2ML+X family [Rauzy & Haskins, 2019, Foundations for Model-Based Systems Engineering and Model-Based Safety Assessment, Journal of Systems Engineering, Wiley Online Library, Vol. 22, pp. 146-155; Batteux, Prosvimova & Rauzy, 2018, From Models of Structures to Structures of Models, IEEE International Symposium on Systems Engineering (ISSE 2018), Rome, Italy], and implemented via a dedicated systemic model management server (120).

The implementation of Σ (Sigma) modeling, meanwhile, relies on a dedicated enterprise architecture framework and method [Krob & Rauzy, 2021, Managing the Systemic Digital Twin of an Industrial Enterprise with WordLab & Σ, CESAMES Systemic Intelligence Pte. Ltd.], derived from the CESAM system architecture framework and method [Krob, 2017, CESAM: CESAMES Systems Architecting Method-A Pocket Guide, CESAM Community; see https://cesam.community/le-guide-cesam/], which involves analyzing industrial assets along three dimensions-operational, functional and organic—with the concrete capabilities provided by the assets in their various operating modes allocated on the organic architecture.

The Σ (Sigma) language is designed to describe usage scenarios for complex technical and socio-technical systems. The associated models are made up of two essential components: a description of the organic architecture of the system under study, and a description of the functional behavior of the system's components.

The description of functional behavior involves processes called activities performed by components. The start-up of each activity depends on the state of the system, takes a certain amount of time, and has a certain effect on the system under study. Both the time taken to carry out an activity and its outcome may be subject to uncertainties, which are described by way of integrated or empirical probability distributions.

In this regard, the Σ (Sigma) technology takes advantage of the research and development carried out around the design of the AltaRica 3.0 modeling language [Batteux, Prosvirnova and Rauzy, 2019, AltaRica 3.0 in 10 Modeling Patterns, International Journal of Critical Computer-Based Systems, Inderscience Publishers, Vol. 9, No. 1-2, p. 133-165; see also the AltaRica association website https://www.altarica-association.org].

### Design and Management of Systemic Proofs

In one embodiment, a dedicated systemic evidence manager (130) is tasked with demonstrating that assets are not currently at risk, or on the contrary, exposing one or more evolutionary scenarios that may potentially put them at risk. The systemic proofs considered are pragmatic, in the sense that they are based on knowledge of the field and require simulations aimed at calculating key asset performance indicators. The calculations to be performed are described in so-called proof scripts.

In one embodiment, the system evidence manager is responsible for executing these scripts to complete the evidence. To do this, the systemic evidence manager dialogues with both the systemic model server and the systemic data extraction server, in order to assemble the models and data from which the key performance indicators are calculated. It also communicates with the system simulation server responsible for performing these calculations.

### System Simulation Management

In one embodiment, the simulations to be carried out are managed by a dedicated systemic simulation server (140). These simulations can be carried out locally or distributed over a network of internal and external computers. The system simulation server is responsible for distributing a simulation according to the workload of the computers on the network. It is also responsible for collecting and collating the results before sending them back to the systemic evidence manager.

1. A method of modeling and simulating a system of systems, involving a technical system of interest and a plurality of systems external to the technical system of interest, forming an environment wherein the technical system of interest evolves, comprises the following steps:
a step of designing one or more scalable digital models of the system of systems, including recording the following elements in digital files:
a description of the system of interest in a hierarchy of systems, comprising for each system a plurality of descriptors of the components of the system and of parameters associated with each of the systems, each of the components being itself modelable as a system, down to the level of an elementary object;
a description of the environment of the system of interest comprising, for each external system with which the system of interest interacts, a hierarchical description similar to that of the system of interest; and
a description of activities carried out by each of the systems involved and interactions between these systems, including:
a plurality of descriptors of laws of internal evolution of their components and laws of dynamic interactions between the system of interest and the other systems with which the system of interest interacts; and
wherein the laws of dynamic interactions are capable of changing, creating, destroying or moving one or more systems in the hierarchy, wherein the laws of dynamic interactions have deterministic or stochastic effects, and are temporized by association with execution times, again deterministic or stochastic, and wherein each system is capable of having its own temporality;
a step of configuring this digital model comprising the following steps:
collecting data sets corresponding to the description of static and/or dynamic parameters for evolution of the systems in question, which may call on internal or external databases;
injecting these data sets into the digital model(s) in an appropriate format; and
defining key performance indicators to be assessed, to support decision-making during at least one of design, deployment, operation, maintenance and dismantling of the system of interest; and
a numerical simulation step enabling the above-mentioned performance indicators to be effectively evaluated, this step comprising the following sub-steps:
defining simulation scenarios involving a plurality of iterations and statistical processing of the calculated values of the performance indicators; and
the actual execution of these simulation scenarios on a set of control units, taking into account the load on each of the control units.

2. The method of claim 1, further comprising raising an alarm in response to the simulations revealing a scenario of evolution of the system of interest presenting a material, economic or environmental risk for the system of interest, an operator of the system of interest, or a system with which the system of interest interacts.

3. The method of claim 1, wherein the plurality of descriptors of the components comprise individual states of the components, levels of stocks handled by the components, and/or performance indicators of the components.
